(19) United States
(12) Patent Application Publication
(10) Pub. No.: US 2012/0146120 A1
(43) Pub. Date: Jun. 14, 2012

(54) Non-Volatile Memory Device

(76) Inventors: Jung-In Han, Hwaseong-si (KR); Sang Eun Lee, Hwaseong-si (KR); Hyouk Sang Yun, Gwangjin-gu (KR); Tong-Hyun Shin, Seoul (KR); June-Ui Song, Yongin-si (KR); Hae-Bum Lee, Suwon-si (KR); Bong-Yong Lee, Suwon-si (KR)

(21) Appl. No.: 13/236,368

(22) Filed: Sep. 19, 2011

(30) Foreign Application Priority Data
Dec. 13, 2010 (KR) 10-2010-0127114

(51) Int. Cl. H01L 29/78; H01L 27/088

(52) U.S. Cl. 257/314; 257/368; 257/E29.255; 257/E27.06

(57) ABSTRACT

A non-volatile memory device includes memory cell active regions and common source active regions extending in parallel on a semiconductor substrate, a self aligned source active region disposed on the semiconductor substrate that intersects the memory cell active regions and the common source active regions and connects the memory cell active regions to the common source active regions, word lines disposed on the memory cell active regions and the common source active regions that intersect the memory cell active regions and the common source active regions, and memory cell transistors formed by the intersection of the word lines and the memory cell active regions, and common source line transistors formed by the intersection of the word lines and the common source active regions, wherein source and drain regions of each of the common source line transistors are separated from each other in the semiconductor substrate.

### CROSS-REFERENCE TO RELATED APPLICATION

This application claims priority under 35 U.S.C. 119 from Korean Patent Application No. 10-2010-0127114 filed on Dec. 13, 2010 in the Korean Intellectual Property Office, the contents of which are herein incorporated by reference in their entirety.

### BACKGROUND

1. Technical Field

The present disclosure is directed to a non-volatile memory device.

2. Description of the Related Art

Semiconductor memory devices may be largely classified into volatile memory devices and non-volatile memory devices. Volatile memory devices can perform data read/write operations quickly, but lose data when the external power supply is interrupted. On the other hand, non-volatile memory devices can store data even when the external power supply is interrupted. Accordingly, non-volatile memory devices are used to store data regardless of power supply. Examples of non-volatile memory devices include a mask read-only memory (MROM), a programmable read-only memory (PROM), an erasable programmable read-only memory (EPROM), an electrically erasable programmable read-only memory (EEPROM), etc.

### SUMMARY

Embodiments of the present disclosure provide a non-volatile memory device capable of simplifying a manufacturing process and improving product reliability.

According to an aspect of the present disclosure, there is provided a non-volatile memory device including memory cell active regions and common source active regions extending in parallel on a semiconductor substrate, a self aligned source active region disposed on the semiconductor substrate that intersects the memory cell active regions and the common source active regions and connects the memory cell active regions to the common source active regions, word lines disposed on the memory cell active regions and the common source active regions that intersect the memory cell active regions and the common source active regions, and memory cell transistors formed by the intersection of the word lines and the memory cell active regions, and common source line transistors formed by the intersection of the word lines and the common source active regions, wherein source and drain regions of each of the common source line transistors are separated from each other in the semiconductor substrate.

According to another aspect of the present disclosure, there is provided a non-volatile memory device including memory cell active regions and common source active regions extending in parallel on a semiconductor substrate, a self aligned source active region disposed on the semiconductor substrate that intersects the memory cell active regions and the common source active regions and connects the memory cell active regions to the common source active regions, word lines disposed on the memory cell active regions and the common source active regions that intersect the memory cell active regions and the common source active regions, and memory cell transistors formed by the intersection of the word lines and the memory cell active regions, and common source line transistors formed by the intersection of the word lines and the common source active regions, wherein the common source line transistors and the memory cell transistors are enhancement type transistors.

According to another aspect of the present disclosure, there is provided a non-volatile memory device including memory cell active regions and common source active regions extending in parallel on a semiconductor substrate, a self aligned source active region disposed on the semiconductor substrate extending perpendicular to the memory cell active regions and the common source active regions and that connects the memory cell active regions to the common source active regions, word lines disposed on the memory cell active regions and the common source active regions that intersect the memory cell active regions and the common source active regions, and memory cell transistors formed by the intersection of the word lines and the memory cell active regions, and common source line transistors formed by the intersection of the word lines and the common source active regions, wherein while no bias voltage is applied to the word lines, no source voltage is applied through the common source line transistors, and when the bias voltage is applied to the word lines, the source voltage is applied to the source region of each of the memory cell transistors through the common source line transistors.

Other aspects of the present disclosure are included in the detailed description and drawings.

### BRIEF DESCRIPTION OF THE DRAWINGS

FIG. 1 illustrates a block diagram of a non-volatile memory device in accordance with an embodiment of the present disclosure.

FIG. 2 is a plan view showing a memory cell array of a non-volatile memory device in accordance with an embodiment of the present disclosure.

FIG. 3 illustrates a circuit diagram of the memory cell array shown in FIG. 2.

FIG. 4 shows a cross-sectional view of the memory cell array taken along lines A-A′ and B-B′ of FIG. 2.

FIG. 5 is a plan view showing a memory cell array of a non-volatile memory device in accordance with another embodiment of the present disclosure.

FIG. 6 illustrates a circuit diagram of the memory cell array shown in FIG. 5.

FIG. 7 is a cross-sectional view of a non-volatile memory device in accordance with still another embodiment of the present disclosure, taken along lines A-A′ and B-B′ of FIG. 2.

FIG. 8 is a diagram that illustrates a method of manufacturing a memory cell array of a non-volatile memory device in accordance with still another embodiment of the present disclosure.

FIGS. 9 to 11 illustrate application examples of a non-volatile memory device in accordance with embodiments of the present disclosure.

### DETAILED DESCRIPTION OF EXEMPLARY EMBODIMENTS

Features of embodiments of the present disclosure and methods of accomplishing the same may be understood more readily by reference to the following detailed description of exemplary embodiments and the accompanying drawings. Embodiments of the present disclosure may, however, be embodied in many different forms and should not be construed as being limited to the exemplary embodiments set forth herein. In the drawings, sizes and relative sizes of layers and regions may be exaggerated for clarity. Throughout the specification, like reference numerals in the drawings denote like elements.

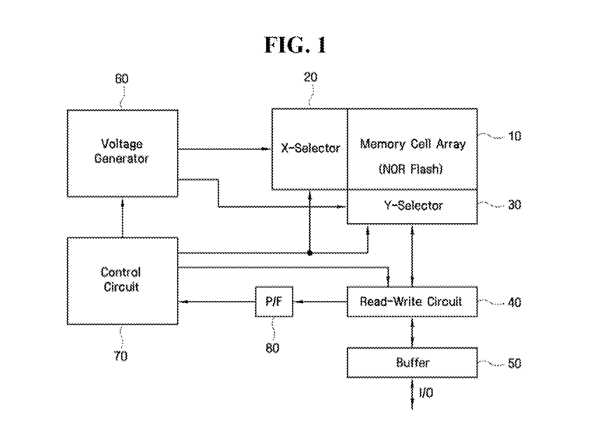

First of all, a non-volatile memory device in accordance with an embodiment of the present disclosure will be described with reference to FIGS. 1 to 4.

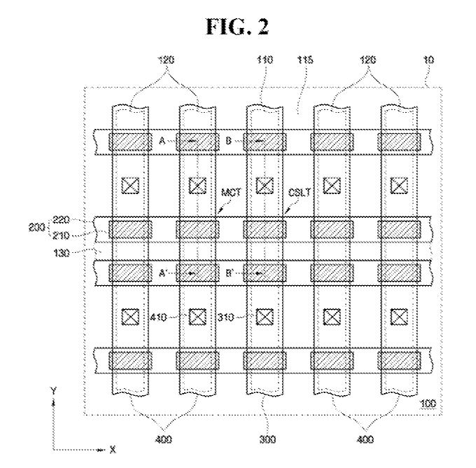

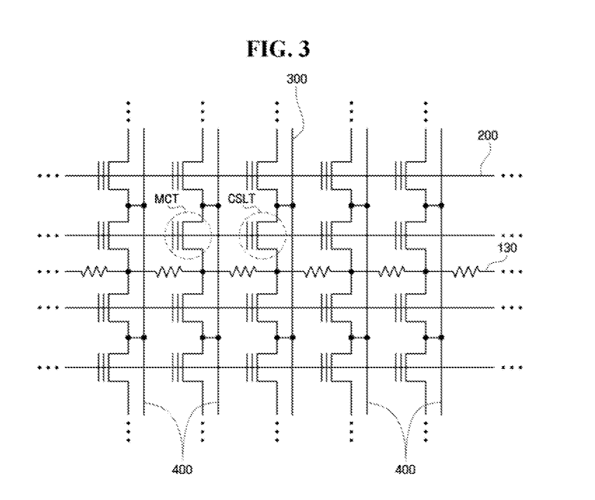

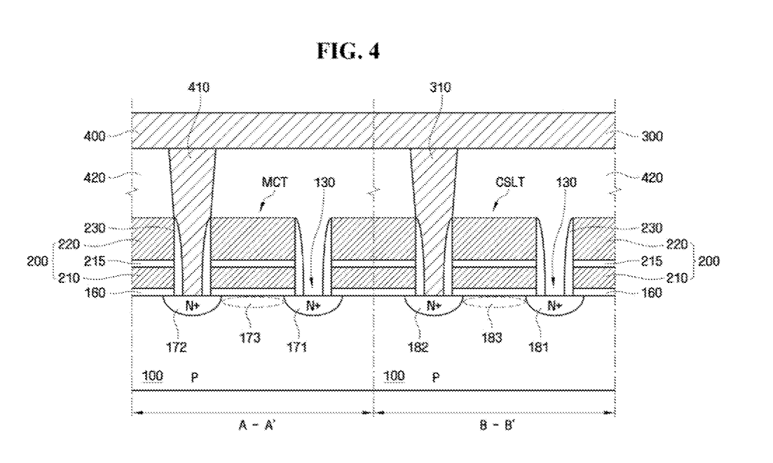

FIG. 1 illustrates a block diagram of a non-volatile memory device in accordance with an embodiment of the present disclosure. FIG. 2 is a plan view showing a portion of a memory cell array of a non-volatile memory device in accordance with an embodiment of the present disclosure. FIG. 3 illustrates a circuit diagram of the memory cell array shown in FIG. 2. FIG. 4 shows a cross-sectional view of the memory cell array taken along lines A-A′ and B-B′ of FIG. 2.

First, referring to FIG. 1, a non-volatile memory device in accordance with an embodiment of the present disclosure may include a memory cell array 10 for storing R-bit data information (R is an integer greater than or equal to 1). The memory cell array 10 may be, e.g., a NOR flash memory cell array. In a case where the memory cell array 10 is configured as a NOR flash memory cell array, a non-volatile memory device in accordance with an embodiment of the present disclosure may be an NOR flash memory cell.

In addition, as shown in FIG. 2, the memory cell array 10 of a non-volatile memory device in accordance with an embodiment of the present disclosure may include a plurality of memory cell transistors MCT and a plurality of common source line transistors CSLT that may be enhancement type transistors. That is, since the memory cell transistors MCT and common source line transistors CSLT shown in FIG. 2 have separated source and drain regions, they may be electrically isolated in a state where no bias voltage is applied thereto. This will be described in detail later with reference to FIGS. 2 to 4.

Referring again to FIG. 1, a row selector (X-selector) 20 may select a memory block (or sector) of the memory cell array 10 in response to a signal from a control circuit 70 and may select a row (e.g., word lines WL) of the selected memory block. Further, the row selector 20 may simultaneously supply a plurality of positive and negative pulses generated from a voltage generator 60 to the selected row and non-selected rows of the memory cell array 10, respectively, in response to the signal from the control circuit 70. A level and timing of the pulse applied to each row may be controlled by the control circuit 70. In addition, a column selector (Y-selector) 30 may select a column (e.g., bit lines BL) of the memory cell array 10 similarly to the row selector 20.

A read-write circuit 40 may be controlled by the control circuit 70, and operate as a sense amplifier or a write driver according to its operation mode as defined by the control circuit. For example, in case of a verify-read operation, the read-write circuit 40 may operate as a sense amplifier for reading data from the memory cell array 10. On the other hand, in case of a program-write operation, the read-write circuit 40 may operate as a write driver for driving columns of the memory cell array 10 according to data to be stored in the memory cell array 10.

A buffer 50 may store data received from an external device, such as a memory controller or host system, and the read-write circuit 40 may use the stored data in a write operation.

The voltage generator 60 may generate a plurality of positive and negative pulses to be supplied to the rows and columns of the memory cell array 10 and the well regions (e.g., memory blocks) in which the memory cells are disposed, according to its operation modes. Operation of the voltage generator 60 may be controlled by the control circuit 70.

The control circuit 70 may directly or indirectly control the row selector 20, the column selector 30, the read-write circuit 40, and the voltage generator 60 to control all operations related to the write, read and erase operations of a non-volatile memory device. Specifically, the control circuit 70 may direct the buffer 50 to load data to be written and the voltage generator 60 to simultaneously apply a plurality of positive and negative pulses to the memory cell array 10 to write to the memory cells or erase the memory cells with the loaded data.

A pass/fail verification circuit 80 may perform a write verify operation of the memory cells during each write verify section in response to the control circuit 70. The verification results obtained by the pass/fail verification circuit 80 may be transmitted to the control circuit 70. The control circuit 70 may determine whether write pulses are to be continuously applied based on the write verification results provided from the pass/fail verification circuit 80. For example, if it is determined that the memory cells are normally written (i.e., pass), no additional write pulses need be applied to complete a write operation of the selected memory cells. On the other hand, if it is determined that the memory cells are not normally written (i.e., fail), a predetermined number of additional write pulses may be applied until all of the memory cells are written.

Although FIG. 1 illustrates a block diagram of an exemplary non-volatile memory device in accordance with an embodiment of the present disclosure, embodiments of the present disclosure are not limited thereto. Namely, if necessary, the arrangement and operation of each block shown in FIG. 1 may be varied without limitation.

Hereinafter, the memory cell array 10 of a non-volatile memory device in accordance with an embodiment of the present disclosure will be described in detail with reference to FIGS. 2 to 4.

As described above, the memory cell array 10 of a non-volatile memory device in accordance with an embodiment of the present disclosure may be, e.g., an NOR flash memory cell array. The NOR flash memory cell array may have various structures, but an exemplary, non-limiting structure thereof will be described below.

Referring to FIGS. 2 and 4, the memory cell array 10 may include a plurality of memory cell active regions 120 and a plurality of common source active regions 110 extending in a first direction (e.g., Y direction) on a semiconductor substrate 100. Although only four memory cell active regions 120 and one common source active region 110 are illustrated in FIG. 2, which shows only a portion of the memory cell array 10, the memory cell active regions 120 and the common source active regions 110 may be repeatedly disposed on the semiconductor substrate 100 in the same pattern as that shown in FIG. 2. Configurations of other components described below may be similarly repeatedly disposed on the semiconductor substrate 100.

Device isolation regions 115 may be formed extending in the first direction between the memory cell active regions 120 and between the common source active regions 110 and the memory cell active regions 120. The device isolation regions 115 may be formed by, for example, Ruining trenches (not shown) in the semiconductor substrate 100, and then filling the trenches with a device isolation film (not shown).

In addition, a self aligned source active region 130 may be disposed extending in a second direction (e.g., X direction) perpendicular to the first direction of the semiconductor substrate 100 to intersect the memory cell active regions 120 and the common source active regions 110 and connect the memory cell active regions 120 to the common source active regions 110. A voltage applied to the common source active regions 110 may be transmitted to each of the memory cell active regions 120 via the self aligned source active region 130. The self aligned source active region 130 may have an intrinsic resistance as shown in FIG. 3.

Word lines 200 may be disposed on the semiconductor substrate 100 extending in the second direction to intersect the memory cell active regions 120 and the common source active regions 110. In particular, in an embodiment of the present disclosure, the word lines 200 may have a linear shape extending in the second direction as shown in FIG. 2. The word lines 200 may include floating gates (210 of FIG. 4) and control gates (220 of FIG. 4) of memory cell transistors MCT and the common source line transistors CSLT, as described in detail below.

Bit lines 400 may be disposed on the memory cell active regions 120 extending in the first direction, and common source lines 300 may be disposed on the common source active regions 110 extending in the first direction. Further, the bit lines 400 and the common source lines 300 may be connected to the memory cell active regions 120 and the common source active regions 110, respectively, via bit line contacts 410 and common source line contacts 310. Although an exemplary arrangement of the bit line contacts 410 and the common source line contacts 310 is illustrated in FIG. 2, the present disclosure is not limited thereto, and if necessary, the arrangement of the bit line contacts 410 and the common source line contacts 310 may be varied without limitation.

Referring again to FIG. 2, the memory cell transistors MCT may be formed where the word lines 200 intersect the memory cell active regions 120, and the common source line transistors CSLT may be formed where the word lines 200 intersect the common source active regions 110. Referring to FIG. 3, the memory cell transistors MCT may be transistors which are biased by a voltage applied to the word lines 200 and store R-bit data information (R is an integer greater than or equal to 1) according to the voltages applied to the bit lines 400 and the semiconductor substrate 100. The common source line transistors CSLT may be transistors which are biased by a voltage applied to the word lines 200 and transmit a voltage applied to the common source lines 300 to the self aligned source active region 130.

The configurations of the memory cell transistors MCT and the common source line transistors CSLT will be described in detail with reference to FIG. 4.

Referring to FIG. 4, each of the memory cell transistors MCT may include the semiconductor substrate 100, a source region 171, a channel region 173 and a drain region 172 disposed in the semiconductor substrate 100, a tunnel oxide film 160, a floating gate 210, a dielectric film 215, a control gate 220, and a spacer 230.

The semiconductor substrate 100 may be of a first conductive type (e.g., P type) as shown in FIG. 4. The source region 171 and the drain region 172 of a second conductive type (e.g., N type) are formed separately from each other in the semiconductor substrate 100, and the channel region 173 of the first conductive type may be formed between the source region 171 and the drain region 172.

The tunnel oxide film 160 may be formed on the second conductive type source and drain regions 171 and 172 and on the first conductive type channel region 173. The tunnel oxide film 160 may be formed of a thermal oxide film. The floating gate 210 may be formed on the tunnel oxide film 160. The floating gate 210 may be formed of a polysilicon film. The floating gate 210 may store electric charges which are received from the channel region 173 and have passed through the tunnel oxide film 160 when a bias voltage is applied to the control gate 220, as described below.

The dielectric film 215 may be disposed between the floating gate 210 and the control gate 220. In this case, the dielectric film 215 may be formed of an oxide-nitride-oxide (ONO) film. The control gate 220 may have a multilayer film structure (not shown in FIG. 4). That is, the control gate 220 may be formed by forming a capping film (not shown), such as a silicon oxide film, on a double film structure including, e.g., a polysilicon film and a metal silicide film such as a tungsten silicide film. The floating gates 210 and the control gates 220 may form the word lines 200 as described above.

The spacer 230 may be formed on the sidewalls of the tunnel oxide film 160, the floating gate 210, the dielectric film 215 and the control gate 220 as shown in FIG. 4. The bit lines 400 and the memory cell transistors MCT may be isolated from each other by an interlayer insulating film 420 as shown in FIG. 4. In this case, the bit line contacts 410 pass through the interlayer insulating film 420 to electrically connect the bit lines 400 to the drain regions 172 of the memory cell transistors MCT.

As described above, since the first conductive type channel region 173 is disposed between the second conductive type source and drain regions 171 and 172, the memory cell transistors MCT of a non-volatile memory device in accordance with an embodiment of the present disclosure have an electrically isolated state if no bias voltage is applied to the word lines 200. Namely, since a threshold voltage of the memory cell transistors MCT is greater than 0 V, the memory cell transistors MCT may be enhancement type transistors.

In addition, the common source line transistors CSLT of a non-volatile memory device in accordance with an embodiment of the present disclosure also may be enhancement type transistors in the same way as the memory cell transistors MCT. In other words, first conductive type channel regions 183 may be disposed between separated second conductive type source and drain regions 181 and 182 to form the common source line transistors CSLT. On the other hand, conventional common source line transistors are depletion type transistors in which the source and drain regions are not separated by a different conductive type region, i.e., the channel region has the same conductive type as the source and drain regions. Accordingly, same as with the memory cell transistors MCT, since a threshold voltage of the common source line transistors CSLT is greater than 0 V, the common source line transistors CSLT have an electrically isolated state if no bias voltage is applied to the word lines 200. Accordingly, while no bias voltage is applied to the word lines 200, no source voltage from the common source lines 300 is supplied to the memory cell transistors MCT through the common source line transistors CSLT. Consequently, the source region 171 of the memory cell transistors MCT has a floating state when no source voltage is applied. If a bias voltage is applied to the word lines 200, a source voltage from the common source lines 300 is applied to the source region 171 of the memory cell transistors MCT through the common source line transistors CSLT.

The configuration of the common source line transistors CSLT is equivalent to the configuration of the memory cell transistors MCT described above, including common source line contacts 310 that pass through the interlayer insulating film 420 to electrically connect the common source lines 300 to the drain regions 182 of the common source line transistors CSLT.

As described above, in a case where the common source line transistors CSLT are configured as enhancement transistors in the same way as the memory cell transistors MCT, it is possible to omit a process for forming the common source line transistors CSLT as depletion transistors, thereby simplifying a manufacturing process. That is, it is possible to omit, e.g., a process for doping the channel regions 183 of the common source line transistors CSLT with second conductive type impurities, thereby simplifying a manufacturing process.

Further, if the channel regions 183 of the common source line transistors CSLT are doped with second conductive type impurities to form the common source line transistors CSLT as depletion transistors, as semiconductor patterns are reduced in size, neighboring elements may be affected by the doping process to change their behavior. However, since the common source line transistors CSLT of a non-volatile memory device in accordance with an embodiment of the present disclosure are configured as enhancement type transistors having separated and electrically disconnected source and drain regions 181 and 182, the above-described effect does not occur.

In addition, in general, a positive voltage is continuously applied to the word lines 200 while a non-volatile memory device in accordance with an embodiment of the present disclosure is being driven. Accordingly, the common source line transistors CSLT continue to maintain a turned-on state. Consequently, the voltage applied to the common source lines 300 is directly transmitted to the self aligned source active region 130 through the turned-on common source line transistors CSLT.

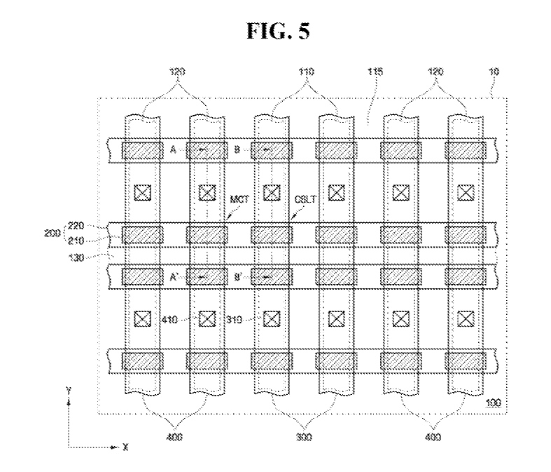

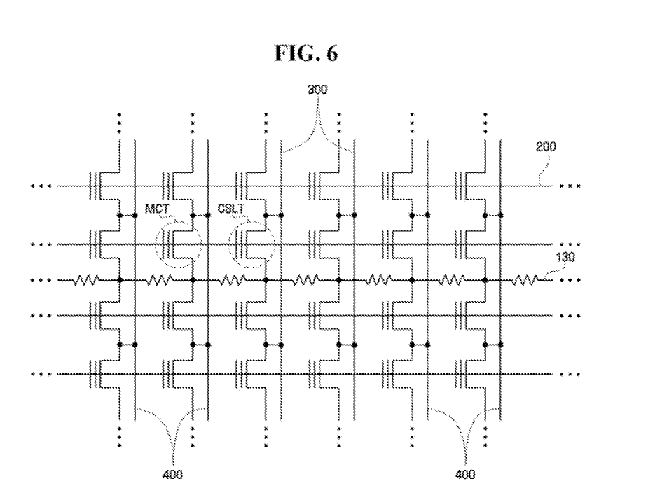

Next, a non-volatile memory device in accordance with another embodiment of the present disclosure will be described with reference to FIGS. 5 and 6.

FIG. 5 is a plan view showing a memory cell array of a non-volatile memory device in accordance with another embodiment of the present disclosure. FIG. 6 illustrates a circuit diagram of a memory cell array shown in FIG. 5. The following description will be given focusing on differences with respect to a non-volatile memory device of an above embodiment of the present disclosure, omitting repeated descriptions thereof.

Referring to FIG. 5, in a memory cell array 10 of a non-volatile memory device in accordance with another embodiment of the present disclosure, at least two common source active regions 110 may be formed extending in a first direction on a semiconductor substrate 100 between a plurality of memory cell active regions 120 extending in the first direction. Accordingly, two adjacent common source line transistors CSLT may form a pair as shown in FIGS. 5 and 6.

As described below, when two common source line transistors CSLT are formed adjacent to each other, it is possible to reduce a channel resistance of the common source line transistors CSLT, thereby more efficiently transmitting a voltage applied to the common source lines 300 to the self aligned source active region 130.

Although a pair of two adjacent common source line transistors CSLT is illustrated in FIGS. 5 and 6, embodiments of the present disclosure are not limited thereto. If necessary, the number of adjacent common source active regions 110 and adjacent common source line transistors CSLT may be increased without limitation.

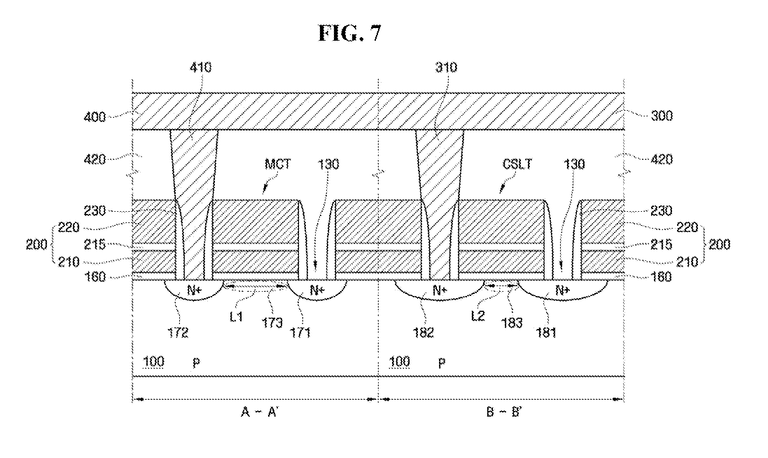

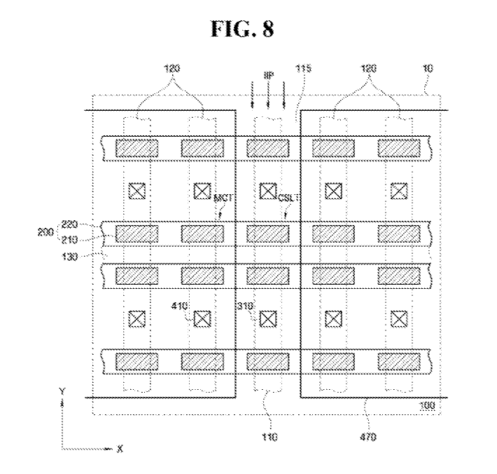

Next, a non-volatile memory device in accordance with still another embodiment of the present disclosure will be described with reference to FIGS. 7 and 8.

FIG. 7 is a cross-sectional view of a non-volatile memory device in accordance with still another embodiment of the present disclosure, taken along lines A-A′ and B-B′ of FIG. 2. FIG. 8 is a diagram that illustrates a method of manufacturing a memory cell array of a non-volatile memory device in accordance with still another embodiment of the present disclosure. Similarly, the following description will be given focusing on differences with respect to above embodiments of the present disclosure, omitting repeated descriptions thereof.

Referring to FIG. 7, a distance L2 between the source and drain regions 181 and 182 of the common source line transistors CSLT in accordance with still another embodiment of the present disclosure may be less than a distance L1 between the source and drain regions 171 and 172 of the memory cell transistors MCT. That is, an effective channel length L2 of the common source line transistors CSLT may be less than an effective channel length L1 of the memory cell transistors MCT. As described below, the effective channel length L2 of the common source line transistors CSLT is made to be less than the effective channel length L1 of the memory cell transistors MCT, to reduce a channel resistance of the common source line transistors CSLT, thereby improving a performance of the common source line transistors CSLT transmitting a voltage applied to the common source lines 300 to the self aligned source active region 130.

In addition, although there are various methods for making the effective channel length L2 of the common source line transistors CSLT to be less than the effective channel length L1 of the memory cell transistors MCT, an exemplary, non-limiting method is illustrated in FIG. 8.

Referring to FIG. 8, after the word lines 200 are formed on the semiconductor substrate 100, the memory cell active regions 120 are masked with a mask 470. Then, when the second conductive type impurities are injected into the exposed common source active regions 110 by ion implantation process IIP, as shown in FIG. 7, the source and drain regions 181 and 182 of the common source line transistors CSLT may be extended. This method is merely exemplary, and the effective channel length L2 of the common source line transistors CSLT may be made less than the effective channel length L1 of the memory cell transistors MCT by other methods.

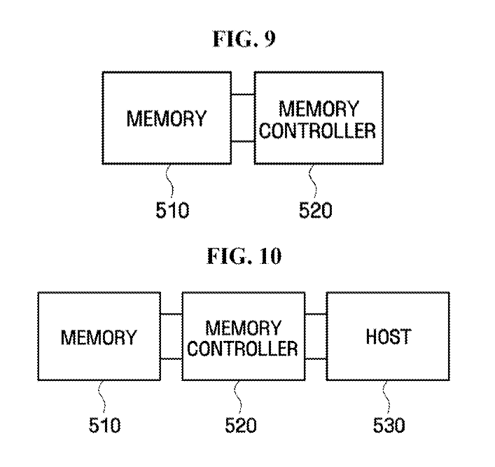

Hereinafter, application examples of a non-volatile memory device in accordance with embodiments of the present disclosure will be described with reference to FIGS. 9 to 11.

FIGS. 9 to 11 illustrate application examples of a non-volatile memory device in accordance with embodiments of the present disclosure.

Referring to FIG. 9, a system in accordance with an embodiment of the present disclosure includes a memory device 510 and a memory controller 520 connected to the memory device 510. In this case, the memory device 510 may be a non-volatile memory device fabricated in accordance with aforementioned embodiments of the present disclosure, which is a memory device capable of simplifying a manufacturing process and improving product reliability as described above. The memory controller 520 may provide an input signal for controlling an operation of the memory device 510, e.g., a command signal and an address signal for controlling a read operation and a write operation, to the memory device 510.

A system including the memory device 510 and the memory controller 520 may be embodied in a card such as a memory card. Specifically, a system in accordance with an embodiment of the present disclosure may be embodied in a card which satisfies a specified industry standard and is used in an electronic device such as a mobile phone, a two-way communication system, a one-way pager, a two-way pager, a personal communication system, a portable computer, a personal data assistant (PDA), an audio and/or video player, a digital and/or video camera, a navigation system, a global positioning system (GPS), etc. However, embodiments are not limited thereto, and a system in accordance with an embodiment of the present disclosure may be embodied in various other forms, such as a memory stick.

Next, referring to FIG. 10, a non-volatile memory system in accordance with another embodiment of the present disclosure may include a memory device 510, a memory controller 520, and a host system 530. In this case, the host system 530 may be connected to the memory controller 520 via, e.g., a bus, and provide a control signal to the memory controller 520, so that the memory controller 520 can control an operation of the memory device 510. The host system 530 may be, for example, a processing system used in a mobile phone, a two-way radio communication system, a one-way pager, a two-way pager, a personal communication system, a portable computer, a PDA, an audio and/or video player, a digital and/or video camera, a navigation system, a GPS, etc.

In addition, although the memory controller 520 is interposed between the memory device 510 and the host system 530 in FIG. 10, embodiments are not limited thereto, and the memory controller 520 may be selectively omitted in a system in accordance with other embodiments of the present disclosure.

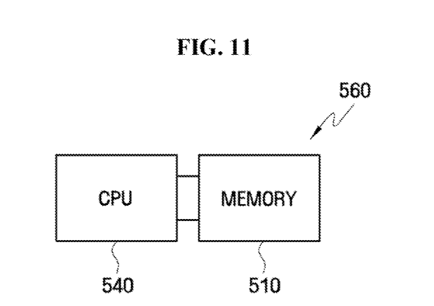

Referring to FIG. 11, a system in accordance with still another embodiment of the present disclosure may be a computer system 560 including a central processing unit (CPU) 540 and a memory device 510. In the computer system 560, the memory device 510 may be connected to the CPU 540 directly or using a typical computer bus architecture. The memory device 510 may store an operating system (OS) instruction set, a basic input/output system (BIOS) instruction set, an advanced configuration and power interface (ACPI) instruction set, etc., or may be used as a large-capacity storage device such as a solid state disk (SSD).

For convenience of explanation, not all components included in the computer system 560 are illustrated in FIG. 11, but embodiments are not limited thereto. Further, for convenience of explanation, the memory controller 520 is omitted between the memory device 510 and the CPU 540 in FIG. 11. However, the memory controller 520 may be interposed between the memory device 510 and the CPU 540 in still another embodiment of the present disclosure.

While embodiments of the present disclosure has been particularly shown and described with reference to exemplary embodiments thereof, it will be understood by those of ordinary skill in the art that various changes in form and detail may be made therein without departing from the spirit and scope of the exemplary embodiments of the present disclosure as defined by the following claims. The exemplary embodiments should be considered in a descriptive sense only and not for purposes of limitation.

What is claimed is:

1. A non-volatile memory device comprising:
memory cell active regions and common source active regions extending in parallel on a semiconductor substrate;
a self aligned source active region disposed on the semiconductor substrate that intersects the memory cell active regions and the common source active regions and connects the memory cell active regions to the common source active regions;
word lines disposed on the memory cell active regions and the common source active regions that intersect the memory cell active regions and the common source active regions; and
memory cell transistors formed by the intersection of the word lines and the memory cell active regions, and common source line transistors formed by the intersection of the word lines and the common source active regions,
wherein source and drain regions of each of the common source line transistors are separated from each other in the semiconductor substrate.

2. The non-volatile memory device of claim 1, wherein the memory cell active regions and the common source active regions extend in a first direction, and
the self aligned source active region and the word lines extend in a second direction perpendicular to the first direction.

3. The non-volatile memory device of claim 1, wherein the semiconductor substrate is of a first conductive type,
the source and drain regions of each of the common source line transistors are of a second conductive type, and further comprising
a channel region of the first conductive type between the source and drain regions of each of the common source line transistors.

4. The non-volatile memory device of claim 3, wherein the first conductive type is a P type, and the second conductive type is an N type.

5. The non-volatile memory device of claim 1, further comprising at least two common source active regions adjacent to each other on the substrate.

6. The non-volatile memory device of claim 1, wherein a distance between the source and drain regions of the common source line transistors is less than a distance between source and drain regions of the memory cell transistors.

7. The non-volatile memory device of claim 1, wherein an effective channel length of the common source line transistors is less than an effective channel length of the memory cell transistors.

8. The non-volatile memory device of claim 1, wherein the non-volatile memory device includes a NOR flash memory device.

9. A non-volatile memory device comprising:
memory cell active regions and common source active regions extending in parallel on a semiconductor substrate;
a self aligned source active region disposed on the semiconductor substrate that intersects the memory cell active regions and the common source active regions and connects the memory cell active regions to the common source active regions;
word lines disposed on the memory cell active regions and the common source active regions that intersect the memory cell active regions and the common source active regions; and
memory cell transistors formed by the intersection of the word lines and the memory cell active regions, and common source line transistors formed by the intersection of the word lines and the common source active regions,
wherein the common source line transistors and the memory cell transistors are enhancement type transistors.

10. The non-volatile memory device of claim 9, wherein the common source line transistors and the memory cell transistors are electrically isolated while no bias voltage is applied to the word lines.

11. The non-volatile memory device of claim 9, wherein a threshold voltage of the common source line transistors and the memory cell transistors is greater than 0 V.

12. The non-volatile memory device of claim 9, further comprising at least two common source active regions adjacent to each other on the substrate.

13. The non-volatile memory device of claim 11, wherein while no bias voltage is applied to the word lines, no source voltage is applied through the common source line transistors, and the source regions of each of the memory cell transistors are floating, and
when the bias voltage is applied to the word lines, the source voltage is applied to the source region of each of the memory cell transistors through the common source line transistors.

14. A non-volatile memory device comprising:
memory cell active regions and common source active regions extending in parallel on a semiconductor substrate;
a self aligned source active region disposed on the semiconductor substrate extending perpendicular to the memory cell active regions and the common source active regions and that connects the memory cell active regions to the common source active regions;
word lines disposed on the memory cell active regions and the common source active regions that intersect the memory cell active regions and the common source active regions; and
memory cell transistors formed by the intersection of the word lines and the memory cell active regions, and common source line transistors formed by the intersection of the word lines and the common source active regions,
wherein while no bias voltage is applied to the word lines, no source voltage is applied through the common source line transistors, and when the bias voltage is applied to the word lines, the source voltage is applied to the source region of each of the memory cell transistors through the common source line transistors.

15. The non-volatile memory device of claim 14, wherein while no bias voltage is applied to the word lines, the common source line transistors and the memory cell transistors are electrically isolated and the source regions of each of the memory cell transistors are floating.

16. The non-volatile memory device of claim 14, wherein a threshold voltage of the common source line transistors and the memory cell transistors is greater than 0 V.

17. The non-volatile memory device of claim 14, wherein the semiconductor substrate is of a first conductive type,
source and drain regions of each of the common source line transistors are of a second conductive type, and further comprising
a channel region of the first conductive type between the source and drain regions of each of the common source line transistors.

18. The non-volatile memory device of claim 14, further comprising at least two common source active regions adjacent to each other on the substrate.

19. The non-volatile memory device of claim 14, wherein a distance between source and drain regions of the common source line transistors is less than a distance between source and drain regions of the memory cell transistors.

20. The non-volatile memory device of claim 1, wherein an effective channel length of the common source line transistors is less than an effective channel length of the memory cell transistors.
